(19) United States
(12) Patent Application Publication
(10) Pub. No.: US 2009/0160022 A1
(43) Pub. Date: Jun. 25, 2009

(54) METHOD OF FABRICATING MIM STRUCTURE CAPACITOR

(76) Inventors: Taek Seung YANG, Seoul (KR); Kang Hyun LEE, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/264,745

(22) Filed: Nov. 4, 2008

(30) Foreign Application Priority Data
Dec. 24, 2007 (KR) 10-2007-0136748

(51) Int. Cl. H01L 29/92; H01L 21/02

(52) U.S. Cl. 257/532; 438/396; 257/E29.343; 257/E21.011

(57) ABSTRACT

The present invention relates to a method of fabricating a MIM structure capacitor. The method includes sequentially depositing a nitride film, a Ti film, and a TiN film over a lower electrode metal layer, the nitride film being an insulating layer, and a combination of the Ti/TiN layers being a upper metal electrode, for the MIM structure capacitor. The method further includes coating a photoresist layer on the upper electrode metal layer and patterning the photoresist layer, then selectively etching the upper metal electrode layer, and the nitride film by using the patterned photoresist layer as an etch mask, and finally removing nitride remaining on sidewalls of the MIM structure capacitor through a wet cleaning process.

### TECHNICAL FIELD

The present invention relates to a method of fabricating a metal/insulator/metal (MIM) structure capacitor and, more particularly, to a method of fabricating a MIM structure capacitor, which can prevent shorting due to byproducts of an insulating layer, which are adhered to sidewalls of the MIM capacitor at the time of patterning in the MIM structure capacitor.

### BACKGROUND

In general, capacitors used in semiconductor devices are largely divided into poly insulator poly (PIP) capacitors and MIM capacitors, depending on the structure. Capacitors having the PIP or MIM structure are properly selected and used according to the desired characteristics of a semiconductor device.

The MIM structure capacitor has been often used in semiconductor devices that use a radio frequency. This is because, in the PIP structure capacitor, upper/lower electrodes formed from conductive polysilicon are used, an oxidization reaction occurs on a surface of the upper/lower electrodes and an insulating thin film and, therefore, the capacitance of the capacitor decreases. The MIM structure capacitor, on the other hand, can be implemented to have a high capacitance since it has low resistivity and does not have parasitic capacitance due to depletion.

In other words, device characteristics of semiconductor devices using a radio frequency can change due to RC delay. Accordingly, semiconductor devices which use a radio frequency generally use the MIM structure capacitor, which is made of metal and has excellent electrical characteristics.

FIG. 1a is a sectional view of a conventional MIM capacitor. As shown in FIG. 1a, in order to form the MIM structure, a lower electrode metal layer, including Ti/TiN films 100 and 102, an AlCu layer 104, and Ti/TiN films 106 and 108, are formed. A nitride film 110, acting as an insulating layer, is deposited on the lower electrode metal layer. An upper electrode metal layer, including Ti/TiN films 112 and 114, is deposited on nitride film 110. A photoresist is coated on the upper electrode metal layer. The photoresist layer is patterned. Then, upper electrode metal layer 112, 114 and nitride film 110 of the insulating layer are sequentially etched using a reactive ion etching (RIE) process by using the patterned photoresist layer as an etch mask, thereby completing the MIM structure.

However, in the above conventional MIM capacitor structure, nitride residue 116 is generated in the metal RIE process, as shown in FIG. 1b. This is because certain process conditions, such as having small etch margins or excellent nitride removal ability, cannot be applied since nitride film 110 used as stop material is thin.

Further, nitride residue 116 generates a change in the property of films in a metal cleaning process and are not removed even in subsequent processes. Nitride residue 116 also can cause pattern failure in subsequent patterning processes, leading to pattern shorting. If an etch time is increased so as to remove nitride residue 116, a problem can arise because etching of sub-layers is also increased which may result in thinner sub-layers.

The above information disclosed in this background section is only for enhancement of understanding of the background of the invention and therefore it may contain information that does not form the prior art that is already known to a person of ordinary skill in the art.

### SUMMARY OF THE INVENTION

Consistent with the present invention, there is provided a method of fabricating a MIM structure capacitor comprising, sequentially depositing a nitride film, a Ti film, and a TiN film over a lower electrode metal layer, the nitride film being an insulating layer, and a combination of the Ti/TiN layers being a upper metal electrode, for the MIM structure capacitor; coating a photoresist layer on the upper electrode metal layer and patterning the photoresist layer; selectively etching the upper metal electrode layer, and the nitride film by using the patterned photoresist layer as an etch mask; and removing nitride remaining on sidewalls of the MIM structure capacitor through a wet cleaning process.

Further consistent with the present invention, there is provided a MIM structure capacitor comprising, a lower electrode metal layer the lower electrode metal layer comprising a first Ti film, a first TiN film, an AlCu layer, a second Ti film, and a second TiN film; a nitride film formed on the lower electrode metal layer; and an upper electrode metal layer, formed on the nitride film, the upper metal electrode layer comprising a third Ti film, and a third TiN film, wherein the capacitor is free from nitride residue on sidewalls of the capacitor.

Additional advantages of the invention will be set forth in part in the description which follows, and in part will be obvious from the description, or may be learned by practice of the invention. The advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate at least one embodiment of the invention and together with the description, serve to explain the principles of the invention.

FIG. 1a is a sectional view of a conventional MIM capacitor.

FIG. 1b is a sectional view of a conventional MIM capacitor which has not undergone a wet cleaning process.

FIG. 2 is a flowchart illustrating a method of fabricating a MIM structure capacitor consistent with the present invention.

FIG. 3 is a flowchart illustrating a wet cleaning process in FIG. 2 consistent with the present invention.

### DETAILED DESCRIPTION

Reference will now be made in detail to the embodiments of the present invention, examples of which are illustrated in the accompanying drawings. Wherever possible, the same reference numbers will be used throughout the drawings to refer to the same or like parts.

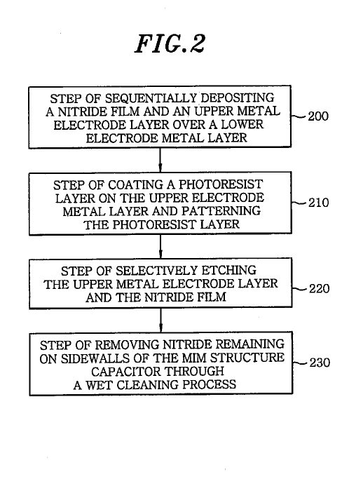

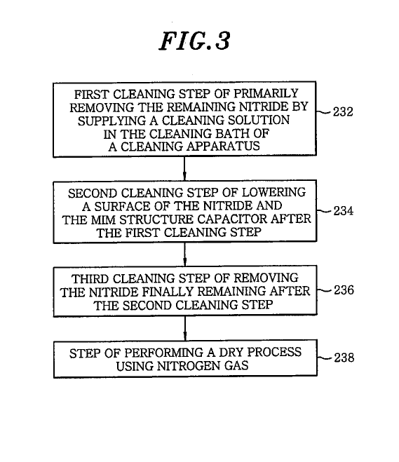

FIG. 2 is a flowchart illustrating a method of fabricating a MIM structure capacitor consistent with the present invention. FIG. 3 is a flowchart illustrating a wet cleaning process in FIG. 2.

Referring to FIGS. 2 and 3, a nitride film, acting as an insulating layer, and Ti/TiN films, constituting an upper metal electrode layer, are sequentially deposited over a lower electrode metal layer in step 200. A photoresist layer is coated on the upper electrode metal layer and the photoresist layer is patterned in step 210. The Ti/TiN films, constituting the upper metal electrode layer, and the nitride film may be selectively etched using the patterned photoresist layer as an etch mask in step 220. Nitride remaining on sidewalls of the MIM structure capacitor may then be removed through a wet cleaning process in step 230.

Here, step 230 of removing nitride remaining on the sidewalls of the MIM structure capacitor through the wet cleaning process includes a first cleaning step 232 of primarily removing the remaining nitride by supplying a cleaning solution in the cleaning bath of a cleaning apparatus, a second cleaning step 234 of lowering a surface of the nitride, which remains after the first cleaning step, and the MIM structure capacitor, a third cleaning step 236 of removing the nitride finally remaining after the second cleaning step, and a step 238 of performing a dry process using nitrogen gas after the third cleaning step.

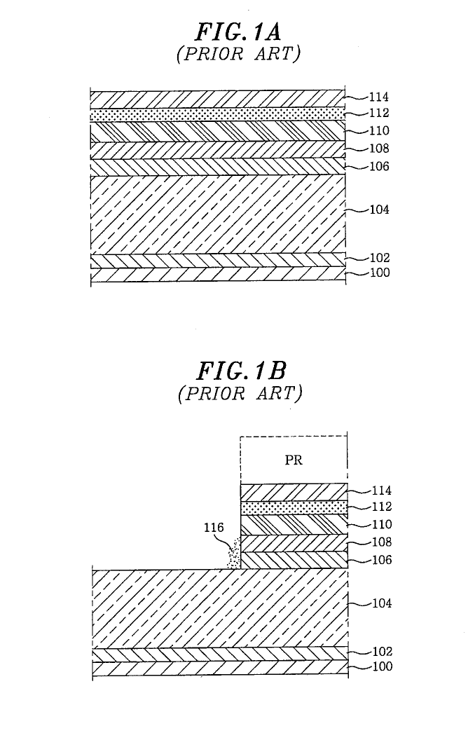

Each of the above steps is described in detail with reference to FIGS. 2 and 3, and FIGS. 1a and 1b.

First, in step 200, the lower electrode metal layer, comprising Ti layers 100, 106 and TiN layers 102, 108, and AlCu layer 104, is deposited using sputtering. Nitride layer 110, being the insulating layer of the MIM structure capacitor, is deposited on the lower electrode metal layer. The upper electrode metal layer, comprising a layer of Ti 112, and a layer of TiN 114 is formed on the nitride film 110.

In steps 210 and 220, the photoresist layer is coated on the upper electrode metal layer and then patterned. Ti/TiN films 112, 114, constituting the upper metal electrode layer, and nitride film 110, acting as an insulator, are sequentially etched selectively through an RIE process using the patterned photoresist layer as an etch mask (not shown), thereby forming the MIM structure.

Here, the lower electrode metal layer may be formed to a thickness ranging from about 500 to 5000 angstroms, and nitride film 220 of the insulating layer may be formed to a thickness ranging from about 50 to 300 angstroms. Further, the upper electrode metal layer includes Ti/TiN films 112, 114, each having a thickness ranging from about 50 to 1000 angstroms/from about 100 to 5000 angstroms, respectively, and the photoresist mask has a thickness of about 13000 angstroms.

Meanwhile, during the metal RIE process performed on the upper electrode metal layer and nitride film 110 of the insulating layer, problems may occur due to nitride residue roughly formed on the surface of the nitride film, as described above.

Therefore, consistent with the present invention, the nitride residue is removed through a wet cleaning process as in step 230.

The wet cleaning process of removing the remaining nitride is described in detail below with reference to FIG. 3. First, the first cleaning step 232 is performed so as to primarily remove the remaining nitride by loading a semiconductor device in which patterns, including metal materials, are formed into the cleaning bath (not shown) of a cleaning apparatus.

In first cleaning step 232, cleaning is primarily carried out by applying a cleaning solution, such as HCl, for about 30 seconds. A rinse process is then carried out using ultrapure water for about 30 seconds.

In second cleaning step 234, in order to protect the sidewalls of the Ti/TiN films and also remove the nitride remaining on the surface of the MIM structure capacitor to some extent, cleaning may be carried out using diluted HF (DHF) for about 12 seconds, and a rinse process may then be performed using ultrapure water for about 12 seconds.

Next, in third cleaning step 236, in order to remove nitride residue that may still remain, cleaning may be carried out using tetramethylammonium hydroxide (TMAH) for about 5 seconds, and a rinse process may then be carried out using ultrapure water for about 30 seconds.

Lastly, after the third cleaning step 236, a dry process using nitrogen gas is performed to thereby complete the wet cleaning process.

As described above, consistent with the present invention, in fabricating a MIM structure capacitor, at the time of the metal RIE process, nitride residue formed by the insulating layer of the MIM structure is removed. Accordingly, the characteristics of the MIM structure capacitor may be improved. Further, the stability of a metal etch process can be ensured and therefore productivity may be improved. Lastly, process margin of subsequent processes can be increased.

As described above, according to the method of fabricating a MIM structure capacitor consistent with the present invention, residue of the insulating layer, occurring when the MIM capacitor is patterned, is removed using wet cleaning processes. Accordingly, the occurrence of shorting may be prohibited and the characteristics of a MIM structure capacitor can be improved.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of fabricating a metal/insulator/metal (MIM) structure capacitor, the method comprising:
sequentially depositing a nitride film, a Ti film, and a TiN film over a lower electrode metal layer, the nitride film being an insulating layer, and a combination of the Ti/TiN layers being a upper metal electrode, for the MIM structure capacitor;
coating a photoresist layer on the upper electrode metal layer and patterning the photoresist layer;
selectively etching the upper metal electrode layer, and the nitride film by using the patterned photoresist layer as an etch mask; and
removing nitride remaining on sidewalls of the MIM structure capacitor through a wet cleaning process.

2. The method of claim 1, wherein removing nitride remaining on sidewalls of the MIM structure capacitor through a wet cleaning process comprises sequentially:
removing the remaining nitride by supplying a first cleaning solution in the cleaning bath of a cleaning apparatus;
removing the remaining nitride by supplying a second cleaning solution in the cleaning bath of the cleaning apparatus,
removing the remaining nitride by supplying a third cleaning solution in the cleaning bath of the cleaning apparatus; and
performing a drying process using nitrogen gas.

3. The method of claim 2, wherein, the first cleaning solution comprises HCl.

4. The method of claim 2, wherein, the second cleaning solution comprises diluted HF (DHF).

5. The method of claim 2, wherein, the third cleaning solution comprises tetramethylammonium hydroxide (TMAH).

6. The method of claim 2, further comprising a cleaning process using ultrapure water after supplying each of the first, second, and third cleaning solutions.

7. A MIM structure capacitor comprising;
a lower electrode metal layer the lower electrode metal layer comprising a first Ti film, a first TiN film, an AlCu layer, a second Ti film, and a second TiN film;
a nitride film formed on the lower electrode metal layer; and
an upper electrode metal layer, formed on the nitride film, the upper metal electrode layer comprising a third Ti film, and a third TiN film, wherein the capacitor is free from nitride residue on sidewalls of the capacitor.

8. The MIM structure capacitor of clam 7, wherein the upper electrode metal layer and the nitride film are sequentially etched using a reactive ion etching (RIE) process by using a patterned photoresist layer as an etch mask.

9. The MIM structure capacitor of clam 7, wherein the lower electrode metal layer has a thickness ranging from about 500 to 5000 Å.

10. The MIM structure capacitor of clam 7, wherein the nitride film of the insulating layer has a thickness ranging from about 50 to 300 Å.

11. The MIM structure capacitor of clam 7, wherein the third Ti film has a thickness ranging from about 50 to 1000 Å, and the third TiN film has a thickness ranging from about 100 to 5000 Å.

12. The MIM structure capacitor of clam 8, wherein the photoresist layer has a thickness ranging from about 3000 to 18000 Å.
